(19) United States
(12) Patent Application Publication
(10) Pub. No.: US 2008/0301536 A1
(43) Pub. Date: Dec. 4, 2008

(54) CHANNEL CODING AND RATE MATCHING FOR LTE CONTROL CHANNELS

(75) Inventors: Sung-Hyuk Shin, Northvale, NJ (US); Donald M. Grieco, Manhasset, NY (US); Nirav B. Shah, Syosset, NY (US); Philip J. Pietraski, Huntington Station, NY (US); Robert Lind Olesen, Huntington, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 12/130,763

(22) Filed: May 30, 2008

Related U.S. Application Data
(60) Provisional application No. 60/941,239, filed on May 31, 2007.

(51) Int. Cl. H03M 13/23; G06F 11/00

(52) U.S. Cl. 714/786; 714/E11.001

(57) ABSTRACT

A method and apparatus for channel coding and rate matching of the Physical Uplink Control Channel (PUCCH) and the Physical Downlink Control Channel (PDCCH) is disclosed that uses convolutional encoding to code the control channels. Rate matching is performed using a circular buffer based rate matching algorithm. A rate matching module may contain a single interleaver or may alternatively comprise a plurality of sub-block interleavers. Interleaved coded bits may be stored in the circular buffer in an interlaced format, or output streams from separate sub-block interleavers may be stored contiguously. When a plurality of sub-block interleavers are used, different interleaving patterns may be used. Rate matching may use bit puncturing or repetition to match the rate of the available physical channel resource. Rate matched output bits may be interleaved using a channel interleaver.

### CROSS REFERENCE TO RELATED APPLICATIONS

This application claims the benefit of U.S. Provisional Application No. 60/941,239, filed on May 31, 2007, which is incorporated by reference as if fully set forth.

### FIELD OF INVENTION

The present invention relates to mobile communication systems. More specifically, the present invention relates to channel coding.

### BACKGROUND

For Long Term Evolution (LTE) data channels, Physical Uplink Shared Channel (PUSCH) and Physical Downlink Shared Channel (PDSCH), the circular buffer (CB) based rate matching (RM) algorithm is applied for Turbo coding, where Turbo coding is used as Forward Error Correction (FEC) coding for the LTE data channels. For LTE control channels, for example Physical Uplink Control Channel (PUCCH) and Physical Downlink Control Channel (PDCCH) (and other common channels), convolutional coding is used as FEC, but details of the FEC, including constraint length and code rate, are for further study (FFS). In addition, rate matching for the control channels is FFS.

### SUMMARY

A system, method and apparatus for channel coding and rate matching for Physical Uplink Control Channel (PUCCH) and Physical Downlink Control Channel (PDCCH) include encoding control channel bits and performing rate matching of the resulting encoded control bits into a given reuse buffer (RB) allocation.

### BRIEF DESCRIPTION OF THE DRAWINGS

A more detailed understanding of the invention may be had from the following description of a preferred embodiment, given by way of example and to be understood in conjunction with the accompanying drawings wherein:

FIG. 1 is an illustration of a channel coding chain for PDCCH and PUCCH;

FIG. 2 is an illustration of rate 1/2 and rate 1/3 convolutional coders;

FIG. 3 is an illustration using a 1/2 rate convolutional code with tail biting and circular buffer based rate matching using a single;

FIG. 4 is an illustration using a 1/2 rate convolutional code with tail biting and circular buffer based rate matching using two sub-block interleavers;

FIG. 5 is an illustration using a 1/3 rate convolutional code with tail biting and circular buffer based rate matching using a single interleaver;

FIG. 6 is an illustration using a 1/3 rate convolutional code with tail biting and circular buffer based rate matching using three sub-block interleavers;

FIG. 7 is an illustration using a 1/2 rate convolutional code with tail bits and circular buffer based rate matching using a single interleaver;

FIG. 8 is an illustration using a 1/2 rate convolutional code with tail bits and circular buffer based rate matching using two sub-block interleavers;

FIG. 9 is an illustration using a 1/3 rate convolutional code with tail bits and circular buffer based rate matching using a single interleaver;

FIG. 10 is an illustration using a 1/3 rate convolutional code with tail bits and circular buffer based rate matching using three sub-block interleavers;

FIG. 11 is an illustration using a 1/2 rate convolutional code with tail biting and Release 4 rate matching;

FIG. 12 is an illustration using a 1/3 rate convolutional code with tail biting and Release 4 rate matching;

FIG. 13 is an illustration using a 1/2 rate convolutional code with tail bits and Release 4 rate matching; and

FIG. 14 is an illustration using a 1/3 rate convolutional code with tail bits and Release 4 rate matching.

### DETAILED DESCRIPTION

When referred to hereafter, the terminology “wireless transmit/receive unit (WTRU)” includes but is not limited to a user equipment (UE), a mobile station, a fixed or mobile subscriber unit, a pager, a cellular telephone, a personal digital assistant (PDA), a computer, or any other type of user device capable of operating in a wireless environment. When referred to hereafter, the terminology “base station” includes but is not limited to a Node-B, a site controller, an access point (AP), or any other type of interfacing device capable of operating in a wireless environment.

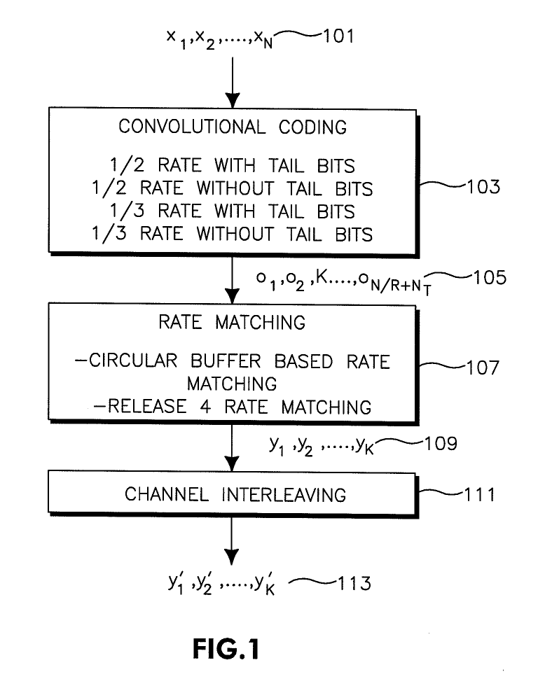

Referring to FIG. 1, the channel coding chain for the Physical downlink control channel (PDCCH) and the physical uplink control channel (PUCCH) is shown. A code block 101 is delivered to the convolutional coding function 103. The code block 101 is denoted as x₁, x₂, . . . , x_{N} where N is the number of bits in the code block 101. After convolution coding 103, the coded bits 105, denoted as o₁, o₂, . . . , o_{N/R+N}_{_{T}} where R is the code rate (e.g. 1/2 or 1/3). The number of coded bits 105 depends on the code rate and the number of tail bits in use as follows:
1/2 rate with tail bits: 2·N+16, where N_{T}=16;
1/2 rate with tail bits removal: 2·N, where N_{T}=0;
1/3 rate with tail bits: 3·N+24, where N_{T}=24;
1/3 rate with tail bits removal: 3·N, where N_{T}=0.

Convolutional codes with constraint length 9 and mother code rates 1/2 and 1/3 may be used, however, the coding and rate matching disclose herein may be used with any constraint length (for example, 7), any encoder polynomial, and/or any mother code rate, for example 1/5 or 1/6. The number of tail bits N_{T} will vary based on constraint length. For example, an embodiment using a constraint length of 7 would use 12 tail bits, i.e. N_{T}=12.

The coded bits 105 are then punctured or repeated to match the available physical channel resources via a rate matching process 107. By way of example, two rate matching algorithms are shown, circular buffer rate matching, and rate matching as specified in Release 4.

After rate matching 107, rate matched bits 109, denoted by y₁, y₂, . . . , YK, where K is the number of transmitted physical control bits, are then permuted by channel interleaving 111. It can be noted that when circular buffer rate matching is used, the channel interleaving process 111 may be omitted as the circular buffer rate matching method involves internal interleaving, as will be described in more detail below, that may play a role in channel interleaving.

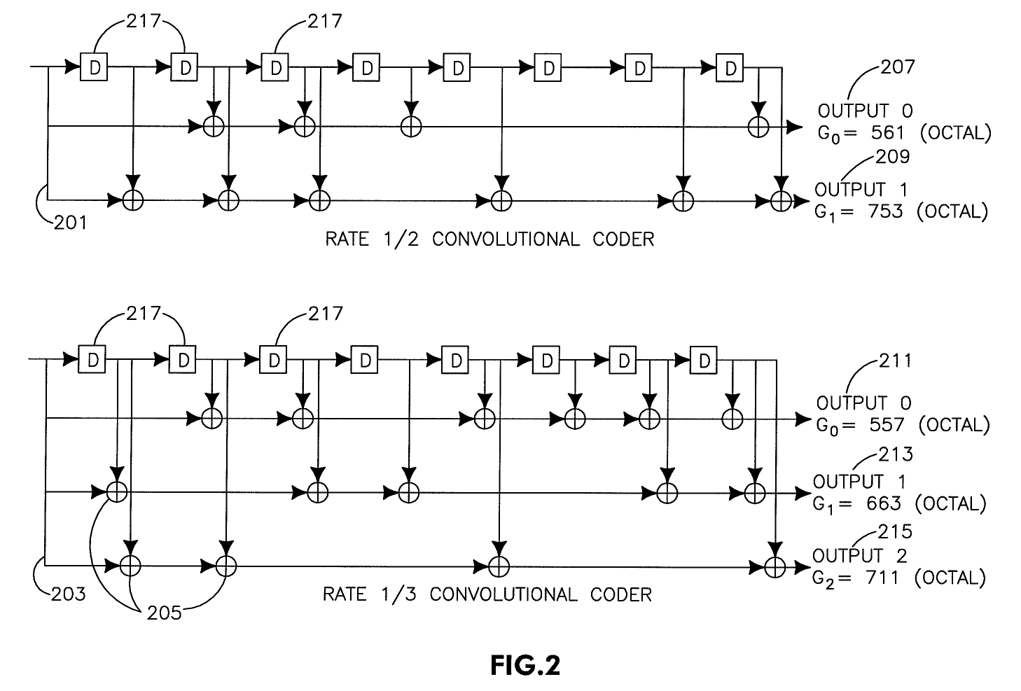

Referring to FIG. 2, two convolutional coders are depicted. A rate 1/2 convolutional encoder 201, and a rate 1/3 convolutional encoder 203. In a rate 1/2 convolutional encoder 201, for every one input bit, two bits are output 207 and 209. In the rate 1/3 convolutional encoder 203, for every one input bit, three bits are output 211, 213, and 215.

As the input bit is convoluted through memory registers 217, the contents of the memory registers 217 are selectively added using modulo 2 adders 205 to arrive at the output bit 207, 209, 211, 213, and 215. A polynomial, denoted as G0, G1, and G2 determines which memory registers 217 are added to calculate a particular output bit 207, 209, 211, 213, and 215.

It should be noted that the number of control channel elements configured for transmission in the PDCCH and the PUCCH could possibly entail multiple control signaling formats. In that case, the number of control channel elements would vary according to the control signaling format. When this happens, multiple rate matching algorithms may be used.

Table 1 lists preferred candidate channel and rate matching combinations that are favorably applicable for LTE control channels and other channels that use convolutional coding.

TABLE 1

| | Coding Scheme | Rate Matching (RM) |
|---|---|---|
| Option-1(a) | 1/2 rate convolutional | Circular buffer based rate matching |
| | coding with tail biting | using a single interleaver |
| Option-1(b) | | Circular buffer based rate matching |
| | | using two sub-block interleavers |
| Option-2(a) | 1/3 rate convolutional | Circular buffer based rate matching |
| | coding with tail biting | using a single interleaver |
| Option-2(b) | | Circular buffer based rate matching |
| | | using three sub-block interleavers |
| Option-3(a) | 1/2 rate convolutional | Circular buffer based rate matching |
| | coding with tail bits | using a single interleaver |
| Option-3(b) | | Circular buffer based rate matching |
| | | using two sub-block interleavers |
| Option-4(a) | 1/3 rate convolutional | Circular buffer based rate matching |
| | coding with tail bits | using a single interleaver |
| Option-4(b) | | Circular buffer based rate matching |
| | | using three sub-block interleavers |
| Option-5 | 1/2 rate convolutional | Release 4 rate matching |
| | coding with tail biting | |
| Option-6 | 1/3 rate convolutional | Release 4 rate matching |
| | coding with tail biting | |
| Option-7 | 1/2 rate convolutional | Release 4 rate matching |
| | coding with tail bits | |
| Option-8 | 1/3 rate convolutional | Release 4 rate matching |
| | coding with tail bits | |

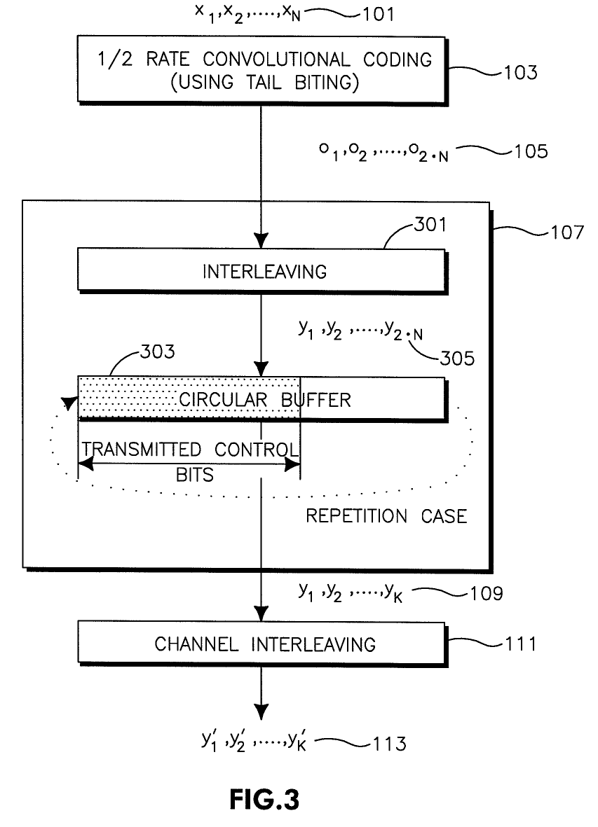

Each of the options in Table 1 will now be described in detail. Referring to FIG. 3, a rate 1/2 convolutional encoder using circular buffer based rate matching 107 and a single sub-block interleaver 201 is shown. A code block 101 of length N, denoted by x₁, x₂, . . . , x_{N} is input to the 1/2 rate convolutional encoder 103. The convolutional code used by the encoder 103, may be convolutional coding provided in Release 99, Release 4 or Release 5/6 as examples, but other convolutional coding methods may be used without departing from the scope and spirit of this disclosure. From the convolutional encoder 103, 2·N coded bits 105 are generated, denoted by o₁, o₂, . . . , o_{2·N}. The coded bits 105 are then permuted by the sub-block interleaver 301 in the circular buffer rate matching 107, resulting in the interleaved coded bits 305, denoted by y₁, y₂, . . . , y_{2·N}.

If puncturing is to be performed, that is, 2·N≧K, then from the interleaved coded bits 305, the first K bits are taken to match K physical channel bits. In the case where 2·N≦K, repetition is performed such that, after reaching the end of the buffer 303, the buffer 303 is read over again from the beginning until K bits (2·N coded bits+(K−2·N) repeated bits) are taken from the buffer.

The resultant rate matched K bits 109, denoted by y₁, y₂, . . . , y_{K} are then permuted using a channel interleaver, if necessary. The final resulting bits 113 are the interleaved, rate matched, coded bits. Convolutional coding and rate matching of the control channel may be performed without the channel interleaver 111, channel interleaving is an optional process that may be omitted without and still fall within the scope of this disclosure.

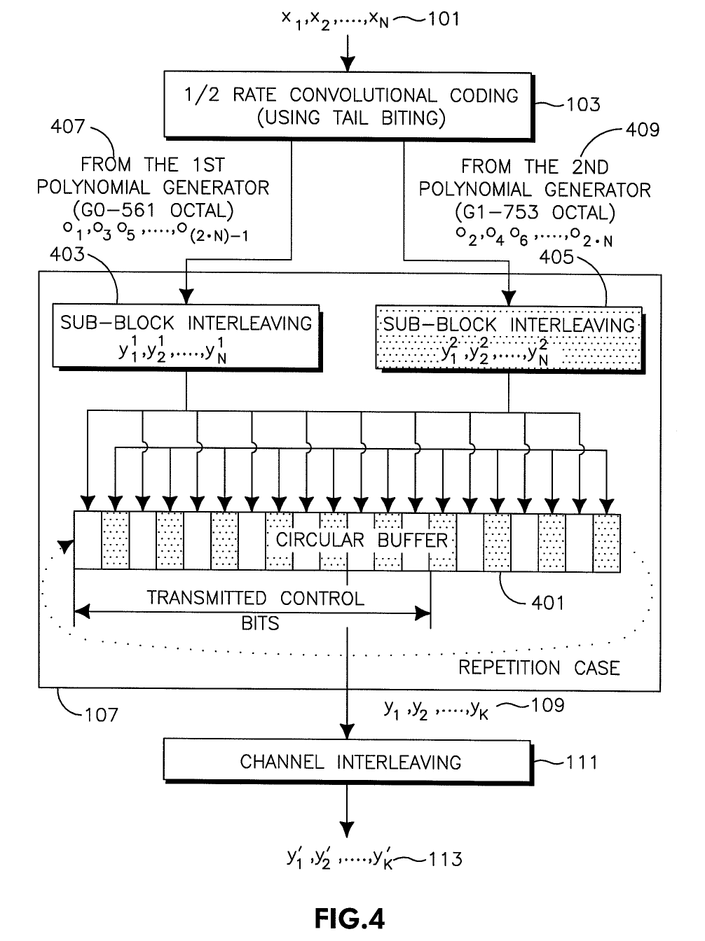

Referring to FIG. 4, a rate 1/2 convolutional encoder using circular buffer based rate matching and two internal sub-block interleavers is shown. The length N bit code block 101 is input to a rate 1/2 convolutional encoder 103 using a circular buffer 401 and two sub-block sub-block interleavers 403 and 405. The convolutional coding 103 generates 2·N coded bits where the bits generated from the first polynomial generator 407 denoted as o₁, o₃, o₅, . . . o_{(2·N)-1} are the input to sub-block interleaver 403. The bits generated from the second polynomial generator 409, denoted as o₂, o₄, o₆, . . . , o_{2·N} are the input to sub-block interleaver 405. The bits are then interlaced into the circular buffer 401.

In an alternative embodiment, the bits generated from the polynomial generators, 407 and 409 may be stored in the circular buffer 401 such that the output stream from each sub-block interleaver 403 and 405 is stored contiguously in the circular buffer 401.

If puncturing is to be performed in the case where 2·N≧K, then from the interlaced bit sequence, the first K bits are taken to match K physical channel bits. Otherwise, in the case where 2·N<K, repetition is performed such that after reaching the end of the buffer 401, the buffer 401 continues to be read from the beginning of the buffer 401 until K bits, i.e. 2·N coded bits+(K−(2·N)) repeated bits are taken from the buffer.

The resulting matched K bits 109, denoted by y₁, y₂, . . . , y_{K} may then be permuted using a channel interleaver 111, if necessary. The output 113 represents convolutional coded, rate matched, interleaved output bits.

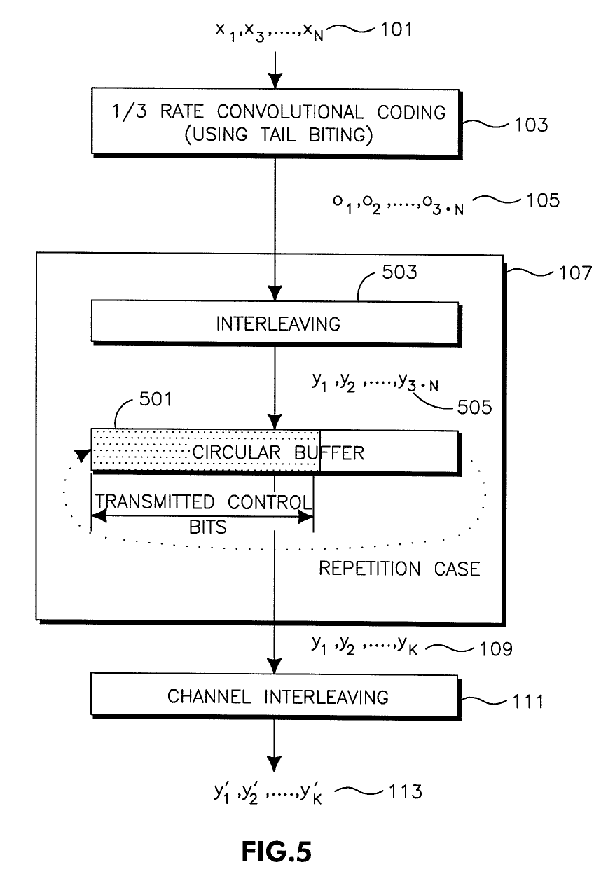

Referring to FIG. 5, a rate 1/3 convolutional encoder 103 using circular buffer rate matching 107 and a single sub-block interleaver 503 is shown. Coded bits 101 with tail biting, with length N, are input to a rate 1/3 convolutional encoder 103 using convolutional code such as Release 4 or Release 5/6 convolutional code. These methods of convolution coding are provided for the purpose of providing examples only, other convolutional coding methods may be used. The encoded bits 105, denoted by o₁, o₂, . . . , o_{3·N}, then enter the circular buffer rate matching 107. In the circular buffer rate matching 107 module, an sub-block interleaver 503 interleaves the coded bits 105 into interleaved, coded bits 505 denoted by y₁, y₂, . . . , y_{3·N}.

If puncturing is to be performed, such as a case where 3·N≧K, then referring to the sequence y₁, y₂, . . . , y_{3·N} the first K bits are taken to match K physical channel bits. Otherwise, when 3·N<K, repetition of bits is performed by re-reading from the beginning of the buffer 501 when the end of the buffer 501 is reached until K bits, 3·N coded bits+(K−(3·N)) repeated bits, are taken from the buffer 501. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

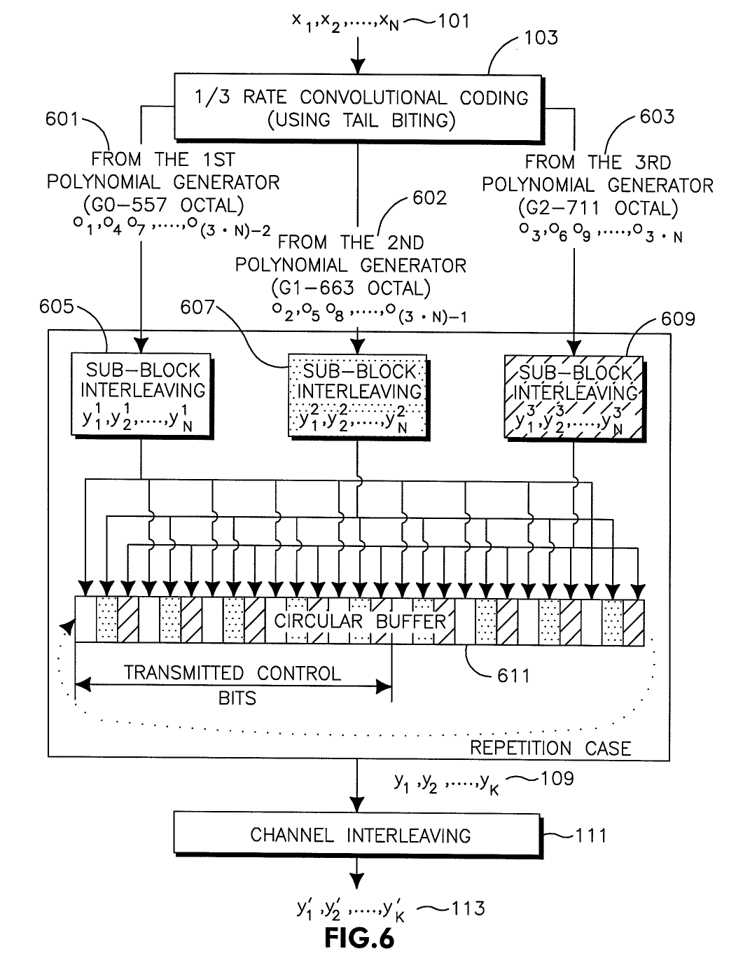

Referring to FIG. 6, channel coding and rate matching using rate 1/3 convolutional coding 103 with tail biting and circular buffer based rate matching 107 with three internal sub-block interleavers 601, 602, 603 is shown. A code block of length N 101, with tail biting, denoted by x₁, x₂, . . . , x_{N}, is input to a rate 1/3 convolutional encoder 103 using a rate 1/3 convolution code such as is specified in the 3GPP long term evolution (LTE) project.

The convolutional encoder 103 generates 3·N coded bits from three polynomial generators 601, 602, and 603 that generate three parity bit streams denoted as o₁, o₄, . . . , o_{(3·N)-}2; o₂, o₅, . . . , o_{(3·N)-1}; and o₃, o₆, . . . , o_{(3·N)}, respectively. The coded bits from the polynomial generators 601, 602, and 603 then enter the circular buffer 611 through three internal sub-block interleavers 605, 607, and 609. Each internal sub-block interleaver 605, 607, and 609 generate interleaved, coded bits denoted by {y¹₁, y¹₂, . . . y¹_{N}}; {y²₁, y²₂, . . . y²_{N}}; and {y³₁, y³₂, . . . , y³_{N}}, respectively. The interleaved, coded bits are then interlaced bit by bit and written to the circular buffer 611.

In an alternative embodiment, the bits generated from the polynomial generators, 605, 607 and 609 may be stored in the circular buffer 611 such that the output stream from each sub-block interleaver 601, 602 and 603 is stored contiguously in the circular buffer 611.

If puncturing is to be performed, such as a case where 3·N≧K, then referring to the sequence y₁, y₂, . . . , y_{3·N}, the first K bits are taken to match K physical channel bits. Otherwise, when 3·N<K, repetition of bits is performed by re-reading from the beginning of the buffer 611 when the end of the buffer 611 is reached until K bits, 3·N coded bits+(K−(3·N)) repeated bits, are taken from the buffer 611. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

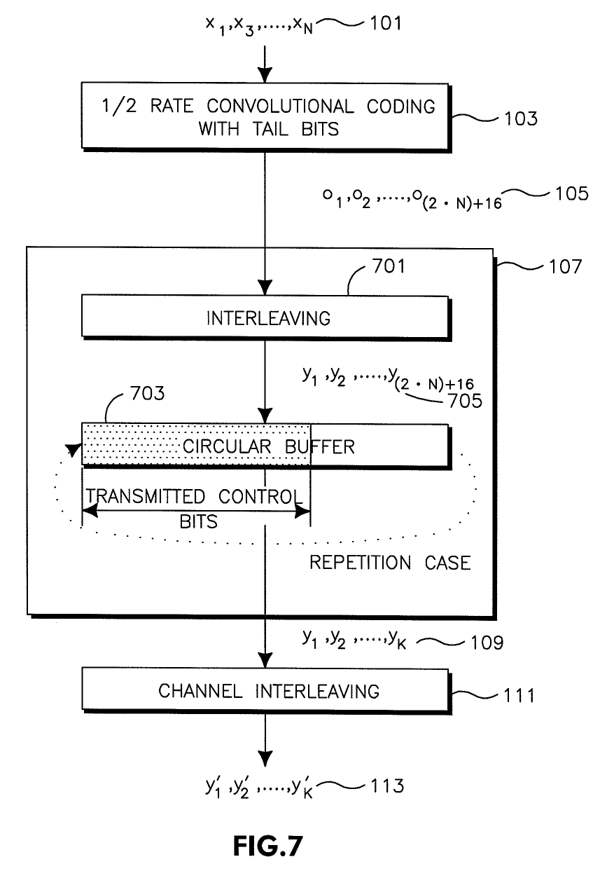

FIG. 7 depicts rate 1/2 convolutional coding with tail bits, using a circular buffer based rate matching scheme 107 utilizing a single sub-block interleaver 701. A code block of length N 101, denoted by x1, x2, . . . , xN is input to a rate 1/2 convolutional encoder using tail bits 103. The rate 1/2 convolutional encoder 103 generates (2·N)+16 coded bits 105, denoted by o1, o2, . . . , o(2·N)+16. The encoded bits 105 are then input to a circular buffer based rate matching scheme 107. The encoded bits are received by a single sub-block interleaver 701 resulting in (2·N)+16 interleaved, coded bits 705, denoted by y1, y2, . . . , y(2·N)+16. The interleaved coded bits 705 are written to a circular buffer 703.

If puncturing is to be performed, such as a case where (2·N)+16≧K, then referring to the sequence y₁, y₂, . . . , y_{2·N+16}, the first K bits are taken to match K physical channel bits. Otherwise, when (2·N)+16<K, repetition of bits is performed by re-reading from the beginning of the buffer 703 when the end of the buffer 703 is reached until K bits, (2·N)+16 coded bits+(K−((2·N)+16)) repeated bits, are taken from the buffer 703. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

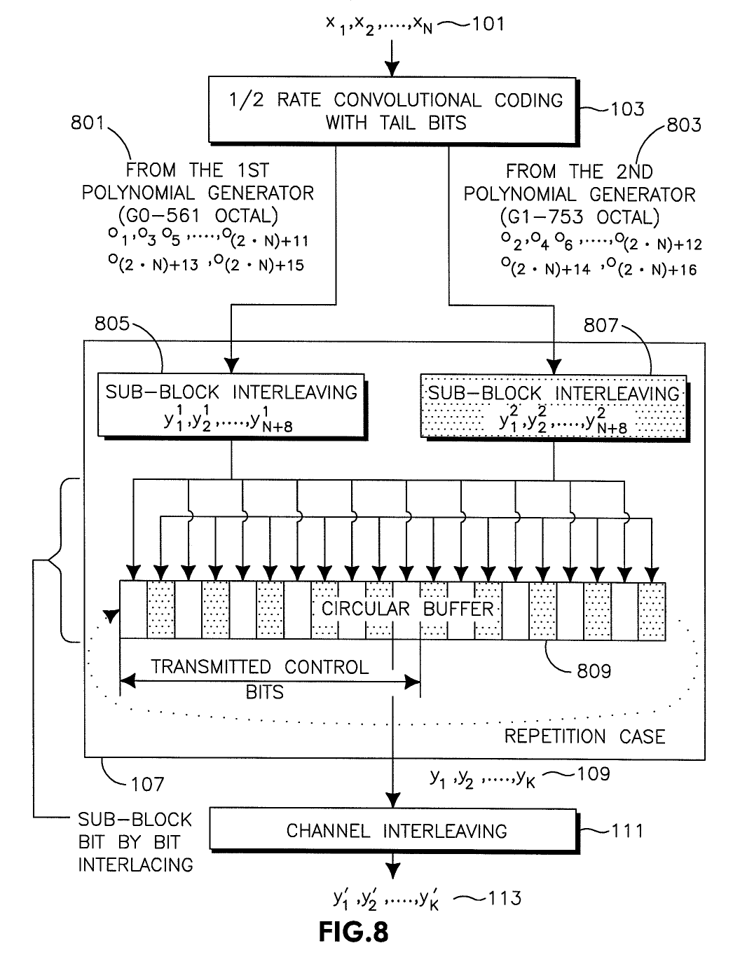

A rate 1/2 convolutional encoder with tail bits 103, using a circular buffer based rate matching scheme 107 utilizing two sub-block interleavers 805 and 807 is shown in FIG. 8. A control block of length N 101, denoted by x₁, x₂, . . . , x_{N} is input to a rate 1/2 convolutional encoder using tail bits 103. The convolutional code used by the rate 1/2 convolutional encoder using tail bits 103, may be a convolutional code such as the convolutional code provided in Release 99, Release 4, or Release 5/6. The rate 1/2 convolutional encoder 103 generates (2·N)+16 coded bits, where the last 16 bits correspond to the tail bits. The (2·N)+16 coded bits are generated by two polynomial generators 801 and 803 that create two separate parity bit streams of the rate 1/2 convolutional code.

The two parity bit streams from the polynomial generators, 801 and 803, denoted by {o₁, o₃, o₅, . . . , o_{(2·N)+15}}; and {o₂, o₄, o₆, . . . , o_{(2·N)+16}}, respectively are separately permuted by the internal sub-block interleavers 805 and 807. The resulting interleaved parity bit streams, denoted by {y¹₁, y²₂, . . . , y¹_{N+8}}; and {y²₁, y²₂, . . . , y²_{N+8}, are interlaced, (e.g. y}¹₁, y²₁, y¹₂, y²₂, . . . , y¹_{N+8}, y²_{N+8}) and written to the circular buffer 809.

In an alternative embodiment, the bits generated from the polynomial generators, 801 and 803 may be stored in the circular buffer 809 such that the output stream from each sub-block interleaver 801 and 803 is stored contiguously in the circular buffer 809.

If puncturing is to be performed, such as a case where (2·N)+16≧K, then referring to the sequence y₁, y₂, . . . , y_{2·N+16}, the first K bits are taken to match K physical channel bits. Otherwise, when (2·N)+16<K, repetition of bits is performed by re-reading from the beginning of the buffer 703 when the end of the buffer 703 is reached until K bits, (2·N)+16 coded bits+(K−((2·N)+16)) repeated bits, are taken from the buffer 703. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

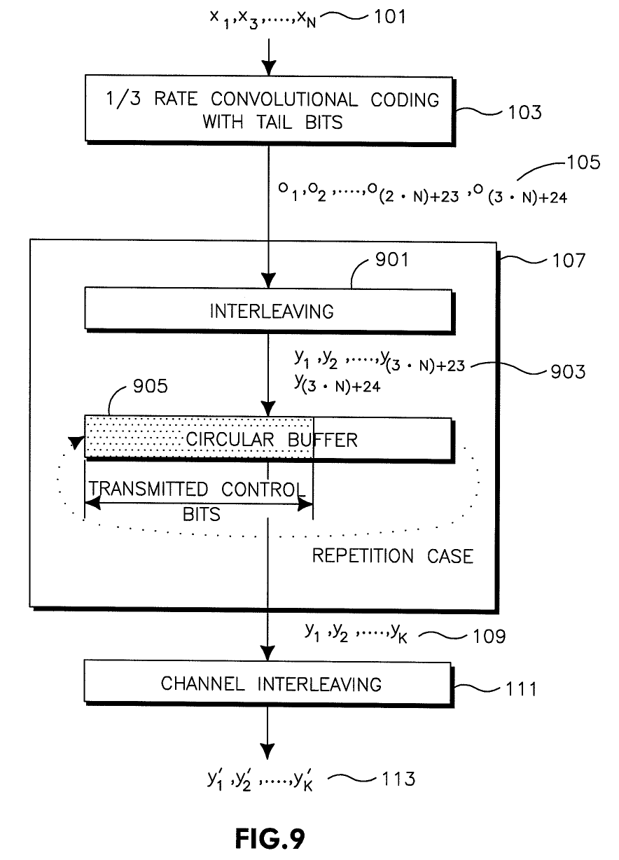

In FIG. 9, a 1/3 rate convolution code with tail bits, using circular buffer based rate matching 107 utilizing a single interleaver 901 is shown.

A code block of length N 101, denoted by x1, x2, . . . , xN, is input to a rate 1/3 convolution encoder 103 using tail bits. The convolutional code generated may be a convolutional code as provided, for example, in Release 99, Release 4, or Release 5/6. The generated coded bits 105, denoted by o1, o2, . . . , o(3·N)+23, o(3·N)+24, are then rate matched using circular buffer based rate matching 107. The coded bits 105 are input to a single, sub-block interleaver 901, producing interleaved coded bits 903, denoted by y1, y2, . . . , y(3·N)+23, y(3·N)+24.

The interleaved, coded bits 903 are stored in a circular buffer 905. If puncturing is to be performed, such as a case where (3·N)+24≧K, then referring to the sequence y₁, y₂, . . . , y_{3·N+24}, the first K bits are taken to match K physical channel bits. Otherwise, when (3·N)+24<K, repetition of bits is performed by re-reading from the beginning of the buffer 905 when the end of the buffer 905 is reached until K bits, (3·N)+24 coded bits+(K−((3·N)+24)) repeated bits, are taken from the buffer 905. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

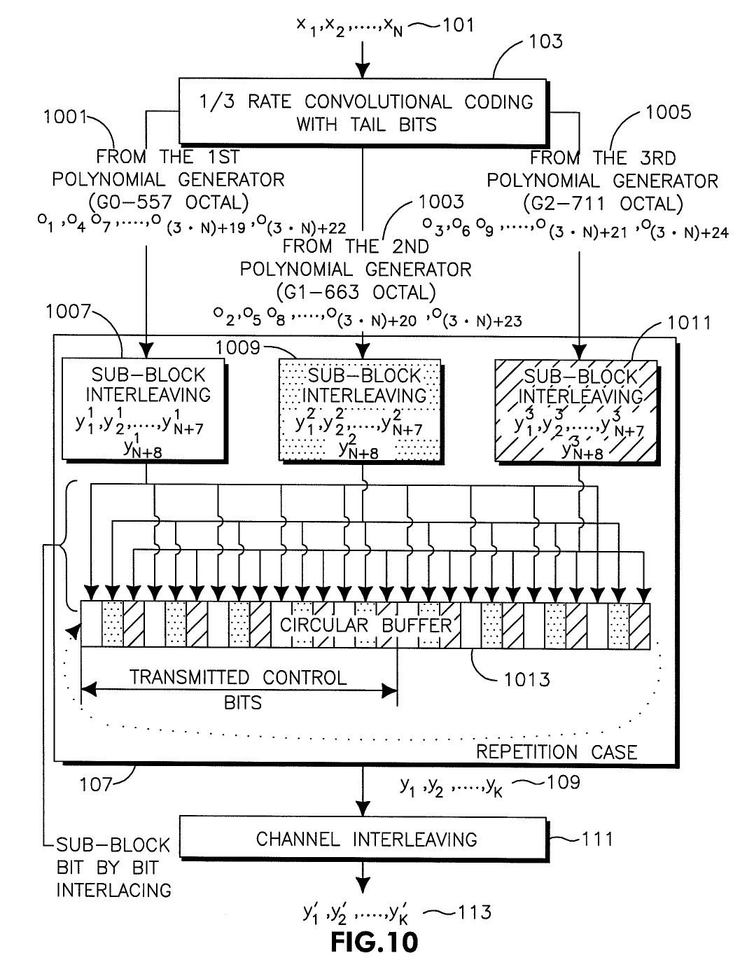

Referring to FIG. 10, a channel coding chain using rate 1/3 convolutional coding 103, circular buffer based rate matching 107 with three internal sub-block interleavers 1007, 1009, and 1011 is shown. A code block of length N 101, with tail biting, denoted by x₁, x₂, . . . , x_{N}, is input to a rate 1/3 convolutional encoder 103 using a rate 1/3 convolution code and tail bits such as is specified in Release 99, Release 4, or Release 5/6.

The convolutional encoder 103 using tail bits generates 3·N+24 coded bits, where the last 24 bits represent the tail bits, from three polynomial generators 1001, 1003, and 1005 that generate three parity bit streams denoted as {o₁, o₄, . . . , o_{(3·N)+22}}; {o₂, o₅, . . . , o_{(3·N)+23}}; and {o₃, o₆, . . . , o_{(3·N)+24}}, respectively. The coded bits from the polynomial generators 1001, 1003, and 1005 then enter the circular buffer based rate matching 107 through three internal sub-block interleavers 1007, 1009, and 1011. Each internal sub-block interleaver 1007, 1009, and 1011 generate interleaved, coded bits denoted by {y¹₁, y¹₂, . . . y¹_{N+8}}; {y²₁, y²₂, . . . y²_{N+8}}; and {y³₁, y³₂, . . . , y³_{N+8}}, respectively. The interleaved, coded bits are then interlaced bit by bit and written to the circular buffer 1013, which may be denoted by, y¹₁, y¹₂, y³₁, y¹₂, y²₂, y³₂, . . . , y¹_{(N*3)+8}, y²_{(N*3)+8}, y³_{(N*3)+8}.

In an alternative embodiment, the bits generated from the polynomial generators, 1001, 1003 and 1005 may be stored in the circular buffer 1013 such that the output stream from each sub-block interleaver 1001, 1003 and 1005 is stored contiguously in the circular buffer 1013.

If puncturing is to be performed, such as a case where (3·N)+24≧K, then referring to the sequence y₁, y₂, . . . , y_{3·N}, the first K bits are taken to match K physical channel bits. Otherwise, when (3·N)+24<K, repetition of bits is performed by re-reading from the beginning of the buffer 1013 when the end of the buffer 1013 is reached until K bits, (3·N)+24 coded bits+(K−(3·N)+24)) repeated bits, are taken from the buffer 1013. The result of the puncturing or repeating are rate matched, coded bits 109, denoted by y₁, y₂, . . . , y_{K}. The rate matched, coded bits 109 may then be input to a channel interleaver 111 if necessary, resulting in the rate matched, coded, interleaved output bits 113.

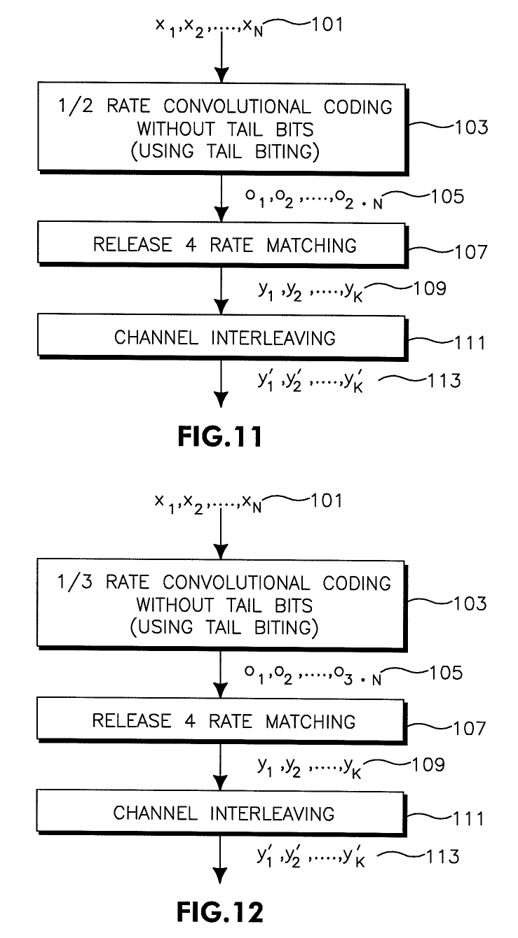

FIG. 11 depicts a channel coding chain in which a rate 1/2 convolutional encoder 103 with tail biting is used with Release 4, Release 5/6, or Release 99 rate matching 107.

A code block of length N 101, denoted by x₁, x₂, . . . , x_{N}, is input to a rate 1/2 convolutional encoder 103, with tail biting, i.e. with tail biting. The convolutional encoder may use a convolutional code as specified in Release 4, Release 5/6 or Release 99. The convolutional encoder 103 will generate 2·N coded bits 105, denoted by o₁, o₂, . . . , o_{2·N}. Rate matching 107 is then performed as described in Release 4, Release 5/6 or Release 99 to arrive at K rate-matched, coded bits 109, denoted by y₁, y₂, . . . , y_{K}. The rate-matched, coded bits 109, may be interleaved by a channel interleaver 111 if necessary to generate an interleaved, rate-matched coded stream 113 denoted by y′₁, y′₂, . . . , y_{K}.

FIG. 12 depicts a channel coding chain in which a rate 1/3 convolutional encoder 103 with tail biting is used with Release 4, Release 5/6, or Release 99 rate matching 107.

A code block of length N 101, denoted by x₁, x₂, . . . , x_{N}, is input to a rate 1/3 convolutional encoder 103, with tail biting, i.e. with tail biting. The convolutional encoder may use a convolutional code as specified in Release 4, Release 5/6 or Release 99. The convolutional encoder 103 will generate 3·N coded bits 105, denoted by o₁, o₂, . . . , o_{3·N}. Rate matching 107 is then performed as described in Release 4, Release 5/6 or Release 99 to arrive at K rate-matched, coded bits 109, denoted by y₁, y₂, . . . , y_{K}. The rate-matched, coded bits 109, may be interleaved by a channel interleaver 111 if necessary to generate an interleaved, rate-matched coded stream 113 denoted by y′₁, y′₂, y′_{K}.

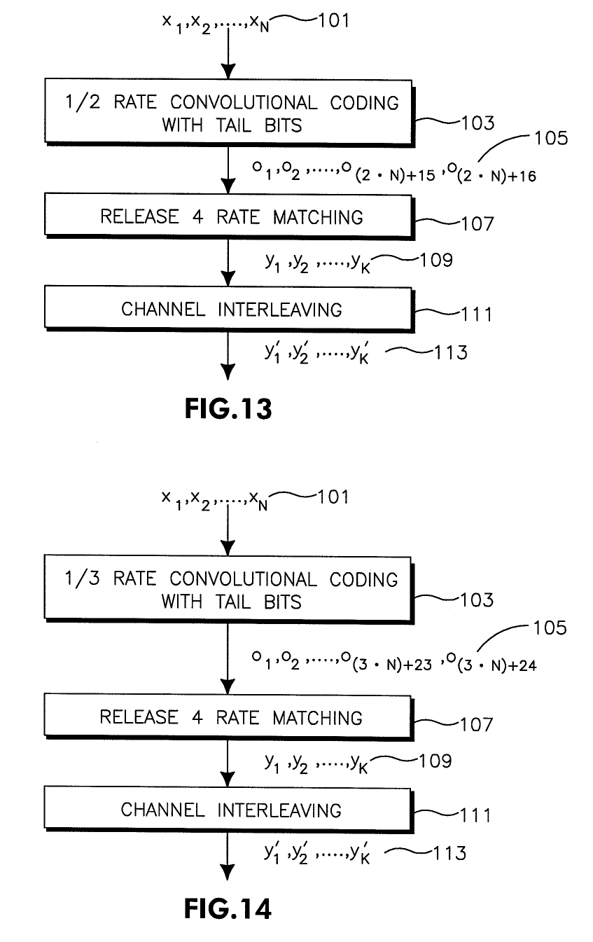

FIG. 13 depicts a channel coding chain in which a rate 1/2 convolutional encoder 103 with tail bits is used with Release 4, Release 5/6, or Release 99 rate matching 107.

A code block of length N 101, denoted by x₁, x₂, . . . , x_{N}, is input to a rate 1/2 convolutional encoder 103, with tail tail bits. The convolutional encoder may use a convolutional code as specified in Release 4, Release 5/6 or Release 99. The convolutional encoder 103 will generate (2·N)+16 coded bits 105, where the last 16 bits correspond to the tail bits, denoted by o₁, o₂, . . . , o_{(2·N)+16}. Rate matching 107 is then performed as described in Release 4, Release 5/6 or Release 99 to arrive at K rate-matched, coded bits 109, denoted by y₁, y₂, . . . , y_{K}. The rate-matched, coded bits 109, may be interleaved by a channel interleaver 111 if necessary to generate an interleaved, rate-matched coded stream 113 denoted by y′₁, y′₂, . . . , y′_{K}.

FIG. 14 depicts a channel coding chain in which a rate 1/3 convolutional encoder 103 with tail bits is used with Release 4, Release 5/6, or Release 99 rate matching 107.

A code block of length N 101, denoted by x₁, x₂, . . . , x_{N}, is input to a rate 1/3 convolutional encoder 103, with tail bits. The convolutional encoder may use a convolutional code as specified in Release 4, Release 5/6 or Release 99. The convolutional encoder 103 will generate (3·N)+24 coded bits 105, denoted by o₁, o₂, . . . , o_{(2·N)+24}. Rate matching 107 is then performed as described in Release 4, Release 5/6 or Release 99 to arrive at K rate-matched, coded bits 109, denoted by y₁, y₂, . . . , y_{K}. The rate-matched, coded bits 109, may be interleaved by a channel interleaver 111 if necessary to generate an interleaved, rate-matched coded stream 113 denoted by y′₁, y′₂, . . . , y′_{K}.

Although features and elements are described above in particular combinations, each feature or element can be used alone without the other features and elements or in various combinations with or without other features and elements. The methods or flow charts provided herein may be implemented in a computer program, software, or firmware incorporated in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

A processor in association with software may be used to implement a radio frequency transceiver for use in a wireless transmit receive unit (WTRU), user equipment (UE), terminal, base station, radio network controller (RNC), or any host computer. The WTRU may be used in conjunction with modules, implemented in hardware and/or software, such as a camera, a video camera module, a videophone, a speakerphone, a vibration device, a speaker, a microphone, a television transceiver, a hands free headset, a keyboard, a Bluetooth® module, a frequency modulated (FM) radio unit, a liquid crystal display (LCD) display unit, an organic light-emitting diode (OLED) display unit, a digital music player, a media player, a video game player module, an Internet browser, and/or any wireless local area network (WLAN) or Ultra Wide Band (UWB) module.

1. A method for coding and rate matching a control channel for use in wireless communications, the method comprising:
receiving a code block, wherein a length of the code block is N bits;
encoding the code block using a convolutional encoder to generate coded bits; and
matching a number of coded bits to an available physical channel resource, wherein a number of bits that may be transmitted on the available physical channel resource is K bits.

2. The method of claim 1, wherein the convolutional encoder is a rate 1/2 convolutional encoder.

3. The method of claim 2, wherein the convolutional encoder uses tail biting.

4. The method of claim 2, wherein matching the number of coded bits to the available physical channel resource uses a circular buffer to store the coded bits.

5. The method of claim 4, wherein the circular buffer is read to the end of the circular buffer, then re-read from the beginning of the circular buffer when the number of generated coded bits is less than K bits.

6. The method of claim 4, wherein the first K bits are read from the circular buffer when the number of generated coded bits is greater than K bits.

7. The method of claim 2 wherein the generated coded bits are interleaved.

8. The method of claim 7, wherein the generated coded bits are interleaved using a single block interleaver.

9. The method of claim 7, wherein the generated coded bits are interleaved using two sub-block interleavers.

10. The method of claim 9, wherein the interleaved generated coded bits are interlaced as they are stored in the circular buffer.

11. The method of claim 9, wherein a generated bit stream corresponding to one of the sub-block interleavers is stored contiguously in the circular buffer.

12. The method of claim 1, wherein the convolutional encoder is a rate 1/3 convolutional encoder.

13. The method of claim 12, wherein the convolutional encoder uses tail biting.

14. The method of claim 12, wherein matching the number of coded bits to the available physical channel resource uses a circular buffer to store the coded bits.

15. The method of claim 14, wherein the circular buffer is read to the end of the circular buffer, then re-read from the beginning of the circular buffer when the number of generated coded bits is less than K bits.

16. The method of claim 15, wherein the first K bits are read from the circular buffer when the number of generated coded bits is greater than K bits.

17. The method of claim 12 wherein the generated coded bits are interleaved.

18. The method of claim 17, wherein the generated coded bits are interleaved using a single block interleaver.

19. The method of claim 17, wherein the generated coded bits are interleaved using three sub-block interleavers.

20. The method of claim 19, wherein the interleaved generated coded bits are interlaced as they are stored in the circular buffer.

21. The method of claim 19, wherein a generated bit stream corresponding to one of the sub-block interleavers is stored contiguously in the circular buffer.

22. A wireless transmit/receive unit (WTRU) for transmitting and receiving control channels in wireless communications, comprising:
a convolutional encoder used to code the control channels; and
a rate-matching module to rate match the control channels, wherein the rate-matching module comprises a circular buffer.

23. The WTRU of claim 22, wherein the convolutional encoder is a rate 1/2 convolutional encoder that generates 2·N coded bits from an N bit input block.

24. The WTRU of claim 22, further comprising a channel interleaver.

25. The WTRU of claim 22, wherein the rate-matching module is configured to output a first K bits of the circular buffer, where K is a number of bits that may be transmitted on an available physical channel resource, when 2·N is greater than K bits.

26. The WTRU of claim 22, wherein the rate-matching module is configured to begin re-reading at a beginning of the circular buffer when an end of the circular buffer is reached, until K bits have been read, where K is a number of bits that may be transmitted on an available physical channel resource, when 2·N is less than K bits.

27. The WTRU of claim 26, wherein the rate-matching module further comprises one block interleaver.

28. The WTRU of claim 26, wherein the rate-matching module further comprises two sub-block interleavers.

29. The WTRU of claim 28, wherein each of the two sub-block interleavers uses a different interleaving pattern.

30. The WTRU of claim 28, wherein an output bit stream from each of the two sub-block interleavers are interlaced bit by bit when stored in the circular buffer.

31. The WTRU of claim 28, wherein an output bit stream from each of the two sub-block interleavers are stored contiguously in the circular buffer.

32. The WTRU of claim 24, wherein the convolutional encoder is a rate 1/3 convolutional encoder that generates 3·N coded bits from an N bit input block.

33. The WTRU of claim 32, wherein the rate-matching module is configured to output a first K bits of the circular buffer, where K is a number of bits that may be transmitted on the available physical channel resource, when 3·N is greater than K bits.

34. The WTRU of claim 32, wherein the rate-matching module is configured to begin re-reading at a beginning of the circular buffer when an end of the circular buffer is reached, until K bits have been read, where K is a number of bits that may be transmitted on the available physical channel resource, when 3·N is less than K bits.

35. The WTRU of claim 32, wherein the rate-matching module further comprises one block interleaver.

36. The WTRU of claim 32, wherein the rate-matching module further comprises three sub-block interleavers.

37. The WTRU of claim 36, wherein each of the three sub-block interleavers uses a different interleaving pattern.

38. The WTRU of claim 36, wherein an output bit stream from each of the three sub-block interleavers are interlaced bit by bit when stored in the circular buffer.

39. The WTRU of claim 36, wherein an output bit stream from each of the three sub-block interleavers are stored contiguously in the circular buffer.

40. A base station for transmitting and receiving control channels in wireless communications, comprising:
a convolutional encoder used to code the control channels; and
a rate-matching module to rate match the control channels, wherein the rate-matching module comprises a circular buffer.

41. The base station of claim 40, further comprising a channel interleaver.

42. The base station of claim 40, wherein the convolutional encoder is a rate 1/2 convolutional encoder that generates 2·N coded bits from an N bit input block.

43. The base station of claim 42, wherein the rate-matching module is configured to output a first K bits of the circular buffer, where K is a number of bits that may be transmitted on an available physical channel resource, when 2·N is greater than K bits.

44. The base station of claim 42, wherein the rate-matching module is configured to begin re-reading at a beginning of the circular buffer when an end of the circular buffer is reached, until K bits have been read, where K is a number of bits that may be transmitted on an available physical channel resource, when 2·N is less than K bits.

45. The base station of claim 42, wherein the rate-matching module further comprises one block interleaver.

46. The base station of claim 42, wherein the rate-matching module further comprises two sub-block interleavers.

47. The WTRU of claim 46, wherein each of the two sub-block interleavers uses a different interleaving pattern.

48. The base station of claim 46, wherein an output bit stream from each of the two sub-block interleavers are interlaced bit by bit when stored in the circular buffer.

49. The base station of claim 46, wherein an output bit stream from each of the two sub-block interleavers are stored contiguously in the circular buffer.

50. The base station of claim 40, wherein the convolutional encoder is a rate 1/3 convolutional encoder that generates 3·N coded bits from an N bit input block.

51. The base station of claim 50, wherein the rate-matching module is configured to output a first K bits of the circular buffer, where K is a number of bits that may be transmitted on an available physical channel resource, when 3·N is greater than K bits.

52. The base station of claim 50, wherein the rate-matching module is configured to begin re-reading at a beginning of the circular buffer when an end of the circular buffer is reached, until K bits have been read, where K is a number of bits that may be transmitted on an available physical channel resource, when 3·N is less than K bits.

53. The base station of claim 50, wherein the rate-matching module further comprises one block interleaver.

54. The base station of claim 50, wherein the rate-matching module further comprises three sub-block interleavers.

55. The WTRU of claim 54, wherein each of the three sub-block interleavers uses a different interleaving pattern.

56. The base station of claim 54, wherein an output bit stream from each of the three sub-block interleavers are interlaced bit by bit when stored in the circular buffer.

57. The base station of claim 54, wherein an output bit stream from each of the three sub-block interleavers are stored contiguously in the circular buffer.

58. A method for coding and rate matching a control channel for use in wireless communications, the method comprising:
receiving an unencoded input block;
convolutionally coding the unencoded input block using a rate 1/3 convolutional encoder, wherein an output stream of encoded bits is output from each encoder polynomial in the rate 1/3 convolutional encoder;
interleaving each output stream of encoded bits using three sub-block interleavers, wherein each sub-block interleaver interleaves one output stream of encoded bits output by an associated encoder polynomial;
storing the interleaved, encoded bits from the sub-block encoders into a circular buffer;
rate matching the stored interleaved encoded bits with a number of bits that may be transmitted on an available physical channel resource, denoted as K bits, wherein repeated stored bits are read from the beginning of the circular buffer when the number of stored interleaved encoded bits is less than K, an wherein the first K bits are read from the circular buffer when the number of stored encoded bits is greater than K.

59. The method of claim 58, wherein the interleaved encoded bits are interlaced as they are stored in the circular buffer.

60. The method of claim 58, wherein the interleaved encoded bits output by each sub-block interleaver are stored contiguously in the circular buffer.
